(19) United States
(12) Patent Application Publication
(10) Pub. No.: US 2023/0411254 A1
(43) Pub. Date: Dec. 21, 2023

(54) MOLDED POWER SEMICONDUCTOR PACKAGE WITH GATE CONNECTOR FEATURE

(71) Applicant: Infineon Technologies AG, Neubiberg (DE)

(72) Inventors: Ivan Nikitin, Regensburg (DE); Christian Neugirg, Regensburg (DE); Karsten Guth, Soest (DE); Gerald Ofner, Regensburg (DE)

(21) Appl. No.: 17/845,280

(22) Filed: Jun. 21, 2022

(51) Int. Cl. H01L 23/495; H01L 23/31; H01L 23/49; H01L 21/48; H01L 21/56

(52) U.S. Cl. CPC H01L 23/49562; H01L 23/3107; H01L 23/49; H01L 23/4952; H01L 23/49575; H01L 21/4825; H01L 21/4842; H01L 21/565

(57) ABSTRACT

A molded power semiconductor package includes power semiconductor dies embedded in a mold compound and a lead frame embedded in the mold compound above the power semiconductor dies. A first part of the lead frame includes branches electrically connected to a first load terminal of the power semiconductor dies. A second part of the lead frame is spaced inward from the branches of the first part, and electrically connected to a gate terminal of the power semiconductor dies. The first part of the lead frame has a protrusion that juts out from a first side face of the mold compound to form a first lead of the molded package. A longitudinal axis of the second part of the lead frame intersects the first lead. The second part of the lead frame is physically disconnected from the first lead by a severed region of the lead frame.

### BACKGROUND

Symmetrical switching of multiple power SiC dies (chips) enables high power applications for 1200V and up to 580 A or more. Conventional molded power semiconductor package designs provide a symmetrical connection for the high-side and low-side switching node connection but the gate contacts for the high side and low side are not symmetrical, which results in different maximal possible switching speeds for the high side and low side. This can lead to oscillations at increased frequencies which can destroy the modules due to high inductive connection of the gate contacts, unless a strong derating is applied for the application.

Hence, there is a need form an improved molded power semiconductor package design suitable for high power applications for 1200V and up to 580 A or more.

### SUMMARY

According to an embodiment of a molded power semiconductor package, the molded power semiconductor package comprises: a mold compound; a plurality of first power semiconductor dies embedded in the mold compound; and a first lead frame embedded in the mold compound above the plurality of first power semiconductor dies, wherein a first part of the first lead frame comprises a plurality of branches electrically connected to a first load terminal of the first power semiconductor dies, wherein a second part of the first lead frame is spaced inward from the branches of the first part, and electrically connected to a gate terminal of the first power semiconductor dies, wherein the first part of the first lead frame has a protrusion that juts out from a first side face of the mold compound to form a first lead of the molded power semiconductor package, wherein a longitudinal axis of the second part of the first lead frame intersects the first lead, wherein the second part of the first lead frame is physically disconnected from the first lead by a severed region of the first lead frame.

According to an embodiment of a method of producing a molded power semiconductor package, the method comprises: positioning a first lead frame above a plurality of first power semiconductor dies, the first lead frame comprising a first part and a second part integrally connected to one another, wherein the first part comprises a plurality of branches and the second part is spaced inward from the branches; electrically connecting the plurality of branches to a first load terminal of the first power semiconductor dies; electrically connecting the second part of the first lead frame to a gate terminal of the first power semiconductor dies; molding the first lead frame and the plurality of first power semiconductor dies with a mold compound, wherein the first part of the first lead frame has a protrusion that juts out from a first side face of the mold compound to form a first lead of the molded power semiconductor package and a longitudinal axis of the second part of the first lead frame intersects the first lead; and after the molding, severing the integral connection between the first part and the second part of the first lead frame such that the first lead becomes physically disconnected from the second part of the first lead frame.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a top perspective view of an embodiment of a molded power semiconductor package having a connection frame.

FIG. 2 illustrates a top perspective view of another embodiment of the molded power semiconductor package.

FIG. 3 illustrates a top plan view of another embodiment of the molded power semiconductor package.

FIGS. 4A and 4B illustrate top plan views of an embodiment of producing the connection frame with different thicknesses.

FIGS. 5A and 5B illustrate top plan views of another embodiment of producing the connection frame with different thicknesses.

FIG. 6A illustrates a top perspective view of another embodiment of the molded power semiconductor package.

FIG. 6B is a cross-sectional view of the molded power semiconductor package along the line labelled B-B′ in FIG. 6A.

FIG. 7 illustrates a top perspective view of another embodiment of the molded power semiconductor package.

FIGS. 8 through 12 illustrate a first embodiment of producing the lead frame gate connections of the molded power semiconductor package.

FIG. 13 illustrates a second embodiment of producing the lead frame gate connections of the molded power semiconductor package.

### DETAILED DESCRIPTION

The embodiments described herein provide a molded power semiconductor package having a connection frame that overlies the power semiconductor dies included in the package and which provides power and gate connections to the power semiconductor dies. A first group of the power semiconductor dies may form a low-side switch of a half-bridge and a second group of the power semiconductor dies may form a high-side switch of the half-bridge. The high-side and low-side power semiconductor dies are mounted to the metallized surface of separate insulative substrates to reduce stray inductance. The connection frame that provides power and gate connections to the power semiconductor dies may have a uniform thickness or regions of different thicknesses to further reduce stray inductances, enabling even higher switching speeds. Further structural features are described for reducing the stray inductance of the connection frame.

A gate contact structure inside the molded power semiconductor package extends along the centerline of the molded power semiconductor package. The gate contact structure may be part of a metal clip frame, a PCB (printed circuit board), an insulative substrate having a metallized surface, or as an additional metal strip insulated from the connection frame, e.g., by mold compound, insulation, glue, insulation foil, etc. Press-fit connectors may be connected to the gate contact structure and partially overmolded to provide external gate connections.

The molded power semiconductor package with the connection frame described herein may have a stray inductance of 7 nH or less, a mostly symmetrical contact structure for multiple power semiconductor dies with low gate inductance, and high symmetry between the high-side switch and low-side switch of a half bridge. The molded power semiconductor package may include four or more power SiC dies (chips) to enable high power applications for up to 1200V or more and up to 580 A or more.

Described next, with reference to the figures, are exemplary embodiments of the molded power semiconductor package and methods of producing such a power semiconductor package. Any of the connection frame and molded power semiconductor package embodiments described herein may be used interchangeably unless otherwise expressly stated.

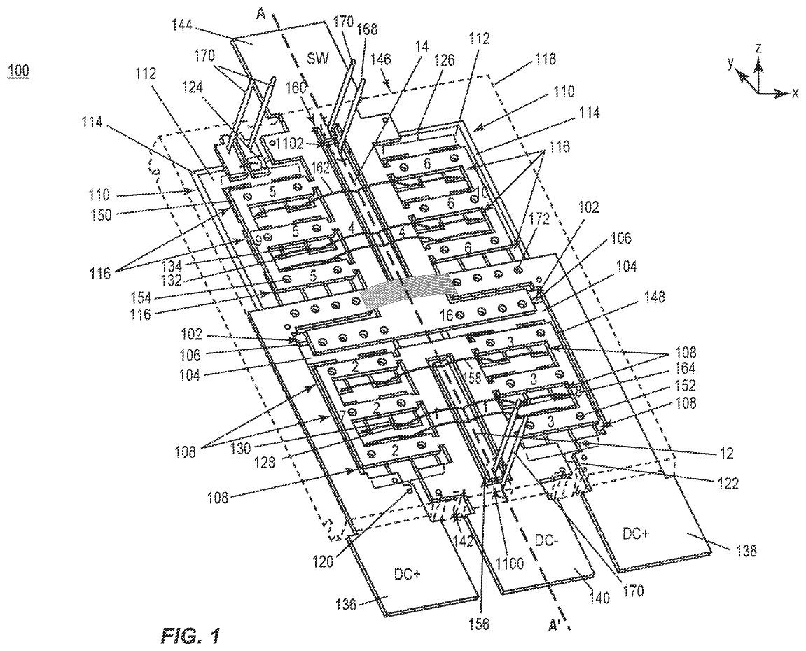

FIG. 1 illustrates a top perspective view of an embodiment of a molded power semiconductor package 100. The molded power semiconductor package 100 may form part of a power electronics circuit for use in various power applications such as in a DC/AC inverter, a DC/DC converter, an AC/DC converter, a DC/AC converter, an AC/AC converter, a multi-phase inverter, an H-bridge, etc.

The molded power semiconductor package 100 includes at least one first power electronics carrier 102 having a metallization layer 104 disposed on an electrically insulating substrate 106. First power semiconductor dies 108 are attached to the metallization layer 104 of the at least one first power electronics carrier 102. The molded power semiconductor package 100 also includes at least one second power electronics carrier 110 having a metallization layer 112 disposed on an electrically insulating substrate 114. Second power semiconductor dies 116 are attached to the metallization layer 112 of the at least one second power electronics carrier 110. A mold compound 118 encases the first power semiconductor dies 108 and the second power semiconductor dies 116, and at least partly encases the at least one first power electronics carrier 102 and the at least one second power electronics carrier 110. In one embodiment, the surface (out of view in FIG. 1) of the first and second power electronics carriers 102, 110 opposite the respective metallization layers 104, 112 is exposed from the mold compound 118 to provided single-sided cooling of the molded power semiconductor package 100.

The outline of the mold compound 118 is shown in FIG. 1 to provide an unobstructed view of the elements encased by the mold compound 118. The at least one first power electronics carrier 102 and the at least one second power electronics carrier 110 are positioned aside one another in the x-y plane instead of being vertically stacked one on top of the other in the z direction.

Each at least one first power electronic carrier 102 and each at least one second power electronics carrier 110 may be, e.g., a DCB (direct copper bonded) substrate, an AMB (active metal brazed) substrate, an IMS (insulated metal substrate), etc. The first power semiconductor dies 108 and the second power semiconductor dies 116 may be power Si or SiC power MOSFET (metal-oxide-semiconductor field-effect transistor) dies, HEMT (high-electron mobility transistor) dies, IGBT (insulated-gate bipolar transistor) dies, JFET (junction filed-effect transistor) dies, etc.

As shown in FIG. 1, the first power semiconductor dies 108 and the second power semiconductor dies 116 are vertical power transistor dies. For a vertical power transistor die, the primary current flow path is between the front and back sides of the die. The drain terminal is typically disposed at the backside of the die, with the gate and source terminals (and optionally one or more sense terminals) at the frontside of the die 110. Additional types of semiconductor dies may be included in the molded power semiconductor package 100, such as power diode dies, logic dies, controller dies, gate driver dies, etc.

The first power semiconductor dies 108 may be attached to the metallization layer 104 of a single first power electronics carrier 102, with a first subset 120 and a second subset 122 of the first power semiconductor dies 108 being symmetrically arranged on the single first power electronics carrier 102 about a longitudinal centerline A-A′ of the molded power semiconductor package 100. The second power semiconductor dies 116 similarly may be attached to the metallization layer 112 of a single second power electronics carrier 110, with a first subset 124 and a second subset 126 of the second power semiconductor dies 116 also being symmetrically arranged on the single second power electronics carrier 110 about the longitudinal centerline A-A′ of the molded power semiconductor package 100.

The first and second subsets 120, 122 of the first power semiconductor dies 108 instead may be attached to separate first power electronics carriers 102 as shown in FIG. 1, with the separate first power electronics carriers 102 being arranged symmetrically with respect to one another about the longitudinal centerline A-A′ of the molded power semiconductor package 100. The first and second subsets 124, 126 of the second power semiconductor dies 116 similarly may be attached to separate second power electronics carriers 110, with the separate second power electronics carriers 110 also being arranged symmetrically with respect to one another about the longitudinal centerline A-A′ of the molded power semiconductor package 100.

In the example illustrated in FIG. 1, the first power semiconductor dies 108 are arranged symmetrically about the package longitudinal centerline A-A′ in three rows (x-direction) with four (two on each side of the longitudinal centerline A-A′) first power semiconductor dies 108 in each row. The second power semiconductor dies 116 are also arranged symmetrically about the package longitudinal centerline A-A′ in three rows (x-direction) with four (two on each side of the longitudinal centerline A-A′) second power semiconductor dies 116 in each row. More generally, the molded power semiconductor package 100 may include at least two first power semiconductor dies 108 and at least two second power semiconductor dies 116, with an equal number of first power semiconductor dies 108 and an equal number of second power semiconductor dies 116 being arranged on both sides of the longitudinal centerline A-A′ of the package 100. This ensures a symmetric layout of both the power semiconductor dies 108, 116 and the power electronics carriers 102, 110 within the molded body 118 of the package 100.

The first power semiconductor dies 108 and the second power semiconductor dies 116 may be electrically coupled as a half bridge, with the first power semiconductor dies 108 forming a low-side switch of the half bridge and the second power semiconductor dies 116 forming a high-side switch of the half bridge. For the vertical die arrangement shown in FIG. 1, the drain terminal (out of view in FIG. 1) of each first power semiconductor die 108 is connected to the metallization layer 104 of the at least one first power electronics carrier 102 with gate and source terminals 128, 130 (and optionally one or more sense terminals) at the opposite frontside of the first dies 108. The drain terminal (out of view in FIG. 1) of each second power semiconductor die 116 is similarly connected to the metallization layer 112 of the at least one second power electronics carrier 110 with gate and source terminals 132, 134 (and optionally one or more sense terminals) at the opposite frontside of the second dies 116.

At least one lead 136, 138, 140 protrudes from a first side face 142 of the mold compound 118 and at least one lead 144 protrudes from a second side face 146 of the mold compound 118 opposite the first side face 142. The longitudinal centerline A-A′ of the molded power semiconductor package 100 extends between the first and second side faces 142, 146 of the mold compound 118.

In FIG. 1, two high-side phase or power leads 136, 138 protrude from the first side face 142 of the mold compound 118 to provide a power/phase connection ‘DC+’ to the second (high-side) power semiconductor dies 116. The first high-side phase/power lead 136 provides the DC+ power/phase connection to the first subset 124 of the second power semiconductor dies 116 and the second high-side phase/power lead 138 provides the DC+ power/phase connection to the second subset 126 of the second power semiconductor dies 116. A low-side phase/ground lead 140 also protrudes from the first side face 142 of the mold compound 118 and provides a power/phase connection ‘DC−’ to the first (low-side) power semiconductor dies 108. The low-side phase/ground lead 140 is interposed between the first and second high-side phase/power leads 136, 138.

A switch node lead 144 protrudes from the second side face 146 of the mold compound 118 and is electrically connected to the switch node ‘SW’ between the high-side power semiconductor dies 116 and the low-side power semiconductor dies 108 of the half bridge. In this case, the switch node lead 144 is the output lead for the molded power semiconductor package 100.

The internal electrical connections between the package leads 136, 138, 140, 144 and the power semiconductor dies 108, 116 encased in the mold compound 118 may be provided by a connection frame overlying the power semiconductor dies 108, 116. In FIG. 1, the connection frame includes a first structured metal frame 148 disposed above the at least one first power electronics carrier 102 and a second structured metal frame 150 disposed above the at least one second power electronics carrier 110. The first structured metal frame 148 and the second structured metal frame 150 may be part of a lead frame with the features of the structured metal frames 148, 150 being formed by stamping, punching, etching, etc.

In FIG. 1, both the first structured metal frame 148 and the second structured metal frame 150 are symmetric about the longitudinal centerline A-A′ of the molded power semiconductor package 100. The terms ‘symmetric’ and ‘symmetrical’ as used herein include unavoidable asymmetry which may arise due to manufacturing tolerances. However, asymmetry may be intentionally introduced into the connection frame formed by the first structured metal frame 148 and the second structured metal frame 150. For example, all semiconductor dies 108, 116 may face the same direction which can introduce a minor asymmetry in the connection frame relative to the center line A-A′ of the molded power semiconductor package 100.

In either case, the first structured metal frame 148 is electrically connected to the source terminal 130 of each first (low-side) power semiconductor die 108, e.g., by bumps or stamped features 152 at the backside of the first structured metal frame 148, or by solder, electrically conductive adhesive, etc. The second structured metal frame 150 is electrically connected to the source terminal 134 of each second (high-side) power semiconductor die 116, e.g., by bumps or stamped features 154 at the backside of the second structured metal frame 150, or by solder, electrically conductive adhesive, etc.

A first subset 120 and a second subset 122 of the first power semiconductor dies 108 may be arranged on opposite sides of the longitudinal centerline A-A′ of the molded power semiconductor package 100, as previously described herein. A first subset 124 and a second subset 126 of the second power semiconductor dies 116 similarly may be arranged on opposite sides of the longitudinal centerline A-A′.

As shown in FIG. 1, the first structured metal frame 148 may include a first central part ‘1’ that extends along the longitudinal centerline A-A′. First branches ‘2’ each joined at a proximal end to the first central part ‘1’ extend in parallel over the first subset 120 of first power semiconductor dies 108 in a first lateral direction (−x direction in FIG. 1) that is transverse to the longitudinal centerline A-A′. Second branches ‘3’ each joined at a proximal end to the first central part ‘1’ extend in parallel over the second subset 122 of first power semiconductor dies 116 in a second lateral direction (x direction in FIG. 1) opposite the first lateral direction.

Further as shown in FIG. 1, the second structured metal frame 150 includes a second central part ‘4’ that extends along the longitudinal centerline A-A′. Third branches ‘5’ each joined at a proximal end to the second central part ‘4’ extend in parallel over the first subset 124 of second power semiconductor dies 116 in the first lateral direction. Fourth branches ‘6’ each joined at a proximal end to the second central part ‘4’ extend in parallel over the second subset 126 of second power semiconductor dies 116 in the second lateral direction.

The first branches ‘2’ of the connection frame are vertically connected to the source terminal 130 of each power semiconductor die 108 included in the first subset 120 of first power semiconductor dies 108. The second branches ‘3’ of the connection frame are vertically connected to the source terminal 130 of each power semiconductor die 108 included in the second subset 122 of first power semiconductor dies 108. The third branches ‘5’ of the connection frame are vertically connected to the source terminal 134 of each power semiconductor die 116 included in the first subset 124 of second power semiconductor dies 116. The fourth branches ‘6’ of the connection frame are vertically connected to the source terminal 134 of each power semiconductor die 116 included in the second subset 126 of second power semiconductor dies 116.

The first structured metal frame 148 of the connection frame may include a first additional ‘7’ branch that connects the first branches ‘2’ at a distal end of the first branches ‘2’, and a second additional branch ‘8’ that connects the second branches ‘3’ at a distal end of the second branches ‘3’. The second structured metal frame 150 of the connection frame may include a third additional branch ‘9’ that connects the third branches ‘5’ at a distal end of the third branches ‘5’, and a fourth additional branch ‘10’ that connects the fourth branches ‘6’ at a distal end of the fourth branches ‘6’.

The first structured metal frame 148 of the connection frame may include a first gate metallization ‘12’ disposed in an opening 156 formed in the first central part ‘1’ of the first structured metal frame 148 and that is electrically insulated from the first central part ‘1’, the first branches ‘2’, and the second branches ‘3’. The first gate metallization ‘12’ is electrically connected to the gate terminal 128 of each first power semiconductor die 108, e.g., by bond wires 158. The second structured metal frame 150 of the connection frame may include a second gate metallization ‘14’ disposed in an opening 160 formed in the second central part ‘4’ of the second structured metal frame 150 and that is electrically insulated from the second central part ‘4’, the third branches ‘5’, and the fourth branches ‘6’. The second gate metallization ‘14’ is electrically connected to the gate terminal 132 of each second power semiconductor die 118, e.g., by bond wires 162.

The first and second gate metallizations ‘12’, ‘14’ may be part of a lead frame, as explained above. The first and second gate metallizations ‘12’, ‘14’ instead may be part of respective first and second PCB disposed in the corresponding openings 156, 160 formed in the first central part ‘1’ and the second central part ‘4’ of the connection frame. In yet another example, the first and second gate metallizations ‘12’, ‘14’ may be part of respective first and second additional power electronics carriers disposed in the corresponding openings 156, 160 formed in the first central part ‘1’ and the second central part ‘4’ of the connection frame.

A first press-fit pin 164 may be attached to the first gate metallization ‘12’ and protrude through the front (top) surface of the mold compound 118. A second press-fit pin 168 may be attached to the second gate metallization ‘14’ and protrude through the front surface of the mold compound 118. The molded power semiconductor package 100 may include additional press-fit pins 170 one or more of which may be attached to the first structured metal frame 148 and/or the second structured metal frame 150 and protruding through the front (top) surface of the mold compound 118, e.g., for external current sensing, temperature sensing, etc.

The second structured metal frame 150 of the connection frame may include an additional branch ‘16’ at the end of the second central part ‘4’ of the second structured metal frame 150 and that faces the first structured metal frame 148. The additional branch ‘16’ extends in parallel with both the third branches ‘5’ and the fourth branches ‘6’ of the second structured metal frame 150. The additional branch ‘16’ is vertically connected to the metallization layer 104 of the at least one first power electronics carrier 102, e.g., by bumps or stamped features 172 at the backside of additional branch ‘16’, or by solder, electrically conductive adhesive, etc.

In FIG. 1, the metallization layer 104 of the least one first power electronics carrier 102 is electrically connected to the drain terminal (out of view) of each first power semiconductor die 108. The metallization layer 112 of the least one second power electronics carrier 110 is electrically connected to the drain terminal (out of view) of each second power semiconductor die 116. The first structured metal frame 148 is electrically connected to the source terminal 130 of each first power semiconductor die 108. The second structured metal frame 150 is electrically connected to the source terminal 134 of each second power semiconductor die 116. The additional branch ‘16’ of the second structured metal frame 150 forms the switch node connection ‘SW’ between the drain terminal of each first power semiconductor die 108 and the source terminal 134 of each second power semiconductor die 116.

In FIG. 1, the first high-side phase/power lead 136 and the second high-side phase/power lead 138 are both electrically connected to the metallization layer 112 of the at least one second power electronics carrier 110. The first high-side phase/power lead 136 flanks one side of the first structured metal frame 148 and the second high-side phase/power lead 138 flanks the opposite side of the first structured metal frame 148 as the first high-side phase/power lead 136.

An end of the first structured metal frame 148 may protrude from the first side face 142 of the mold compound 118 to form the low-side phase/ground lead 140 of the molded power semiconductor package 100. An end of the second structured metal frame 150 may protrude from the second side face 146 of the mold compound 118 to form the switch node lead 144 of the molded power semiconductor package 100.

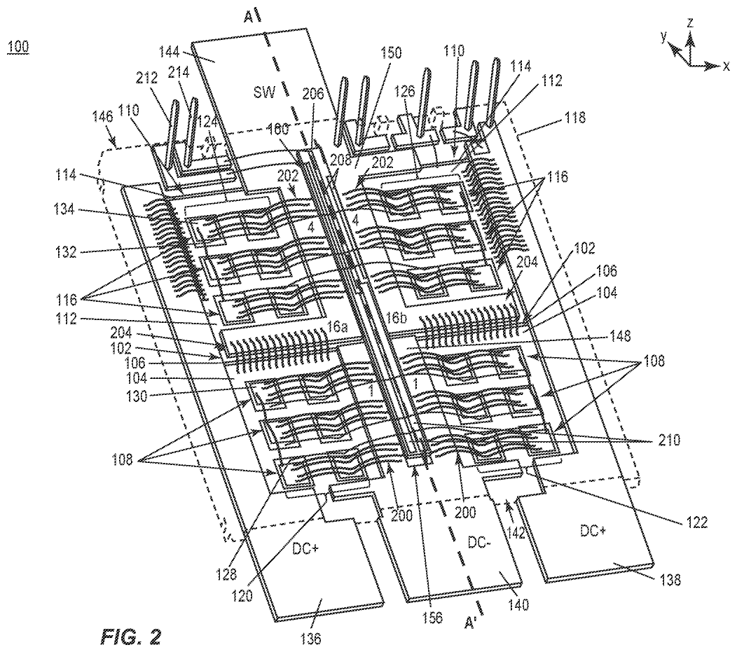

FIG. 2 illustrates a top perspective view of another embodiment of the molded power semiconductor package 100. According to the embodiment in FIG. 2, the source connections to the first power semiconductor dies 108 are formed by first bond wires 200 which connect the first central part ‘1’ of the first structured metal frame 148 to the source terminal 130 of each first power semiconductor die 108. The source connections to the second power semiconductor dies 116 are similarly formed by second bond wires 202 which connect the second central part ‘4’ of the second structured metal frame 150 to the source terminal 134 of each second power semiconductor die 116. Accordingly, branches ‘2’, ‘3’, ‘7’ and ‘8’ of the first structured metal frame 148 and branches ‘5’, ‘6’, ‘9’ and ‘10’ of the second structured metal frame 150 are omitted from the connection frame and replaced by bond wires 200, 202 in FIG. 2. The additional branch ‘16’ of the second structured metal frame 150 is electrically connected to the metallization layer 104 of the at least one first power electronics carrier 102 by third bond wires 204 in FIG. 2 to complete the switch node connection ‘SW’.

In FIG. 2, the gate connections to the power semiconductor dies 108, 116 are provided by at least one PCB 206 disposed in the opening 156 formed in the first central part ‘1’ of the first structured metal frame 148 and in the opening 160 formed in the second central part ‘4’ of the second structured metal frame 150. The at least one PCB 206 has one or more first metal traces 208 electrically connected to the gate terminal 128 of each first power semiconductor die 108 and one or more second metal traces 210 electrically connected to the gate terminal 132 of each second power semiconductor die 116. The external gate connections may be provided by respective press-fit connectors 212, 214. The at least one PCB 206 may instead by at least one additional power electronics carrier such as a DCB substrate, an AMB substrate, an IMS, etc.

In FIG. 2, the first structured metal frame 148 is wire bonded to the source terminal 130 of each first power semiconductor die 108 and the second structured metal frame 150 is wire bonded to the source terminal 134 of each second power semiconductor die 116. The additional branch ‘16’ of the second structured metal frame 150 may be divided into two segments ‘16a’, ‘16b’ to accommodate the at least one PCB/power electronics carrier 206 that provides the gate connections to the power semiconductor dies 108, 116. Each segment ‘16a’, ‘16b’ of the additional branch ‘16’ of the second structured metal frame 150 is wire bonded to the metallization layer 104 of a first power electronics carrier 102 to form the switch node connection ‘SW’ between the drain terminal (out of view) of each first power semiconductor die 108 and the source terminal 134 of each second power semiconductor die 116.

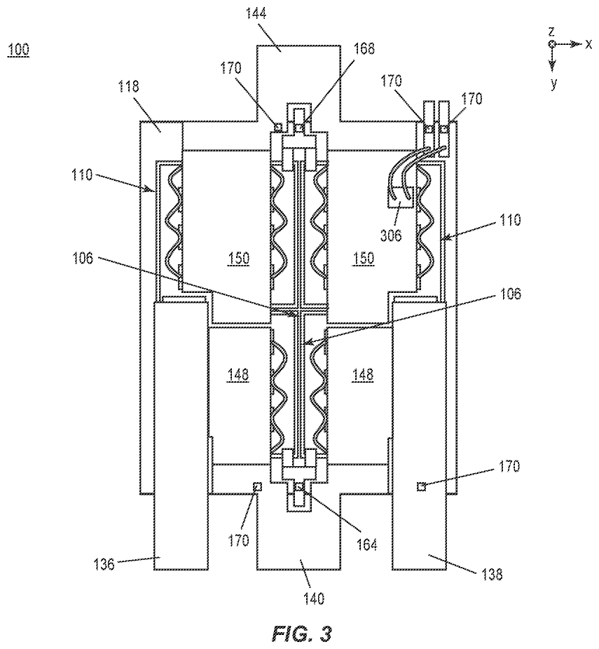

FIG. 3 illustrates a top plan view of another embodiment of the molded power semiconductor package 100. The mold compound 118 is only shown around the edge of the package 100, to provide an unobstructed view of the elements encased by the mold compound 118.

In FIG. 3, the two high-side phase or power leads 136, 138 are each thicker than both the first structured metal frame 148 and the second structured metal frame 150. The low-side phase/ground lead 140 for the half bridge, which is laterally interposed between the high-side phase or power leads 136, 138, is vertically connected to the first structured metal frame 148 and thicker than both the first structured metal frame 148 and the second structured metal frame 150. The switch node lead 144 for the half bridge is vertically connected to the second structured metal frame 150 and thicker than both the first structured metal frame 148 and the second structured metal frame 150. The first and second structured metal frames 148, 150 are made thinner than the package leads 136, 138, 140, 144 in FIG. 2 to reduce stray inductance.

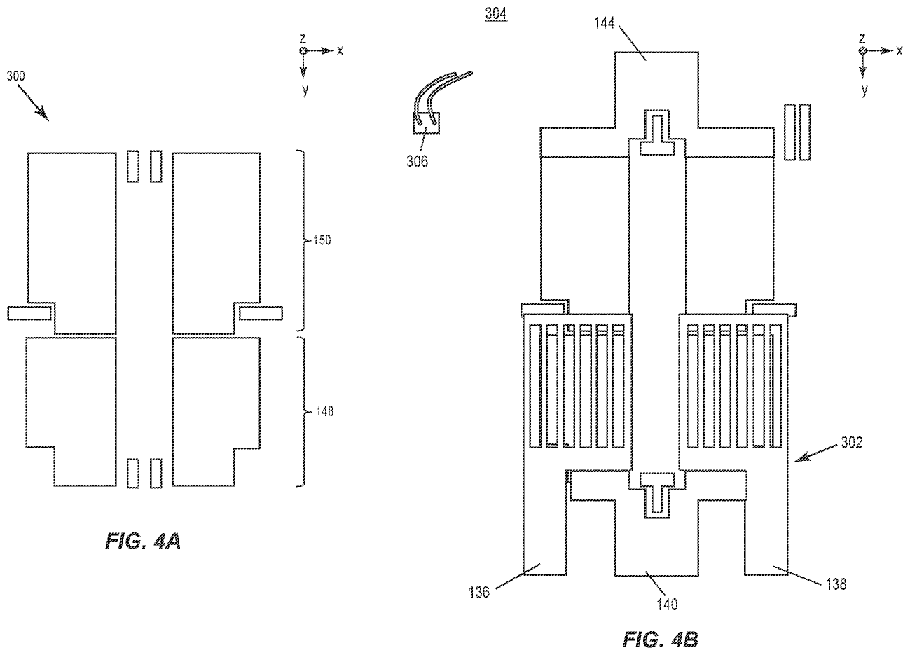

FIGS. 4A and 4B illustrate top plan views of an embodiment of producing the connection frame with different thicknesses.

FIG. 4A shows the first structured metal frame 148 and the second structured metal frame 150. The first structured metal frame 148 and the second structured metal frame 150 may be part of a first lead frame 300 with the features of the structured metal frames 148, 150 being formed by stamping, punching, etching, etc.

FIG. 4B shows a second lead frame 302 overlying and attached to the first lead frame 300. The first and second lead frames 300, 302 may be soldered or welded together, e.g., to form a multi-layer lead frame 304 that may be processed further as a single lead frame. The second lead frame 302 includes the package leads 136, 138, 140, 144 and additional metal structures some of which may be electrically connected to a sensor 306 such as an NTC (negative temperature coefficient) temperature sensor, e.g., as shown in FIG. 3. The metal structures of the second lead frame 302 may be formed by stamping, punching, etching, etc. The second lead frame 302 is thicker than the first lead frame 300, which allows additional routing and provides the leads 136, 138, 140, 144 outside the molded body 118.

For example, the first lead frame 300, which includes the first and second structured metal frames 148, 150, may have a thickness less than 0.5 mm, e.g., of about 0.25 mm. The second lead frame 302, which includes the package leads 136, 138, 140, 144, may have a thickness greater than 0.5 mm and less than 1 mm, e.g., of about 0.8 mm. Other lead frame thickness combinations may be used, with the second lead frame 302 being thicker than the first lead frame 300. The multi-layer lead frame 304 is then attached to the power electronics carriers 102, 110 and the power semiconductor dies 108, 116, as previously described herein and as shown in FIG. 3.

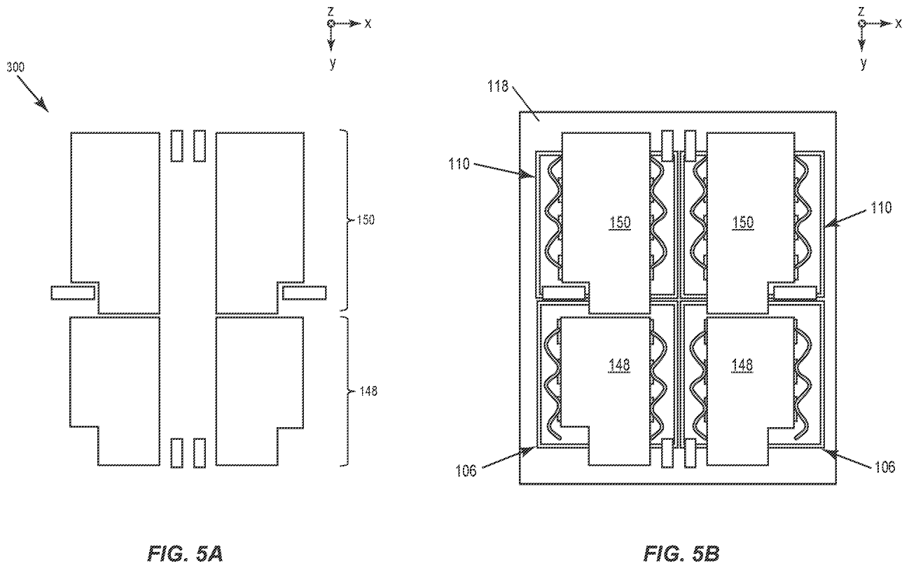

FIGS. 5A and 5B illustrate top plan views of another embodiment of producing the connection frame with different thicknesses.

FIG. 5A shows the first structured metal frame 148 and the second structured metal frame 150. The first structured metal frame 148 and the second structured metal frame 150 may be part of a first lead frame 300 with the features of the structured metal frames 148, 150 being formed by stamping, punching, etching, etc.

FIG. 5B shows the first lead frame 300 attached to the source terminals 128, 132 of the power semiconductor dies 108, 116 as previously described herein in connection with FIG. 1. Different than the embodiment illustrated in FIGS. 4A and 4B, the first lead frame 300 is attached to the source terminals 128, 132 of the power semiconductor dies 108, 116 in FIG. 5A before attaching the second lead frame 302 to the first lead frame 300. After the first lead frame 300 is attached to the source terminals 128, 132 of the power semiconductor dies 108, the second lead frame 302 is attached to the first lead frame 300, e.g., by soldering, welding, etc. to yield the structure shown in FIG. 3.

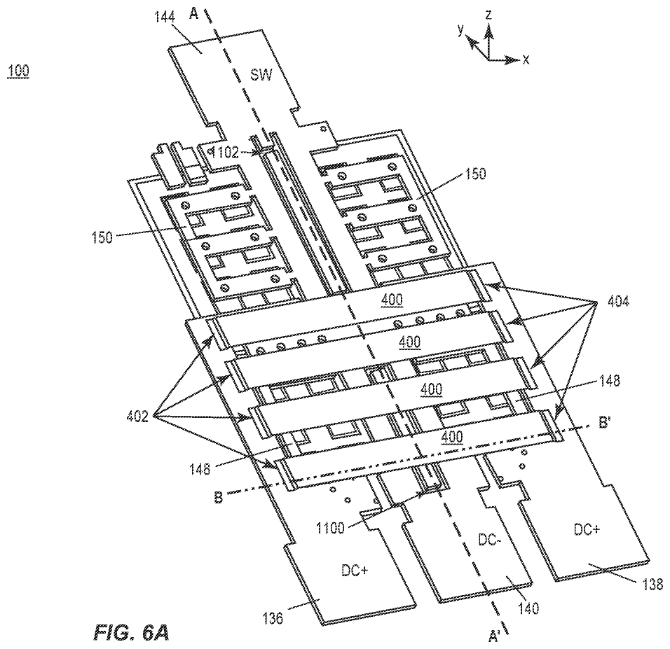

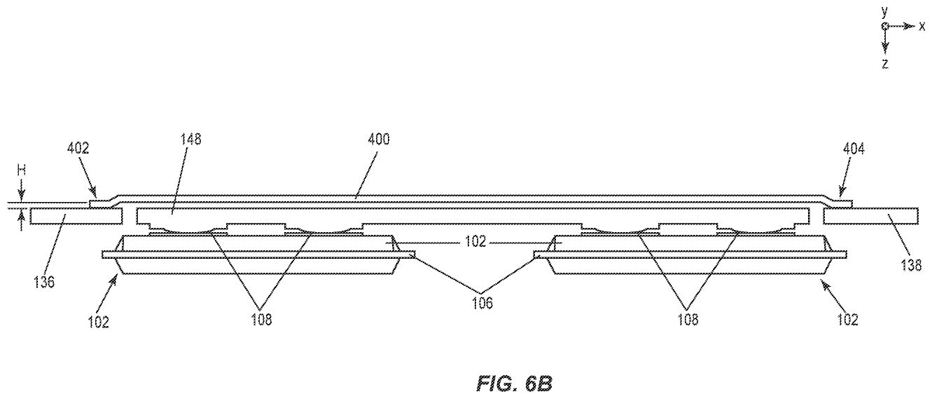

FIGS. 6A and 6B illustrate another embodiment of the molded power semiconductor package 100. FIG. 6A is a top perspective view of the molded power semiconductor package 100. FIG. 6B is a cross-sectional view of the molded power semiconductor package 100 along the line labelled B-B′ in FIG. 6A. The mold compound 118 is not shown in FIGS. 6A and 6B, to provide an unobstructed view of the elements encased by the mold compound 118.

FIG. 6A shows the same carrier, die, and connection frame layout as FIG. 1. Accordingly, most of the reference numbers are omitted from FIG. 6A to provide a clearer view of the additional features first illustrated in FIG. 6A.

In FIG. 6A, metal strips or a single metal sheet 400 are connected at a first end 402 to the first high-side phase/power lead 136 and at a second end 404 to the second high-side phase/power lead 138. The metal strips or single metal sheet 400 span the first structured metal frame 148, as shown in FIG. 6B. In the case of metal strips, Cu ribbons or Al ribbons may be connected to the high-side phase/power leads 136, 138 by a ribbon-bonding process such as ultrasonic welding or laser-assisted ultrasonic welding. In the case of a single metal sheet, a Cu or Al sheet may be soldered to the high-side phase/power leads 136, 138.

Placing the metal strips or a single metal sheet 400 over the power contacts inside of the molded power semiconductor package 100 reduces the stray inductance by about 28%, e.g., from about 9.1 nH for the embodiment in FIG. 1 to about 6.6 nH for the embodiment in FIGS. 6A and 6B, as calculated without the positive influence of a cooler. The stray inductance improvement is even greater compared to the wire bond embodiment of FIG. 2, which has a stray inductance of about 11 nH.

As shown in FIG. 6B, the metal strips or single metal sheet 400 may be placed with defined form and height ‘H’ over the first contact metal layer. The height ‘H’ may range from 50 to 1000 μm for ensuring insulation properties. The smaller the height ‘H’, the lower stray inductance expected. A clearance height in the range of 300 to 500 μm is typically required for standard molding compound.

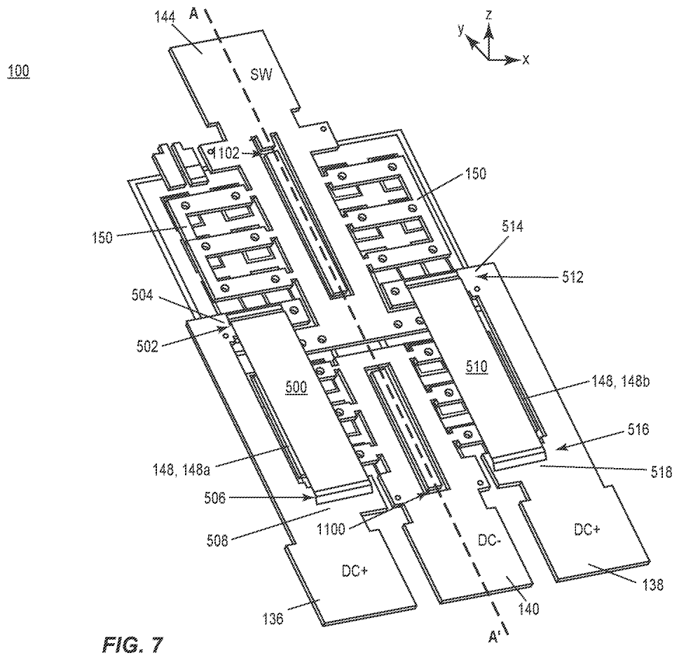

FIG. 7. illustrates a top perspective view of another embodiment of the molded power semiconductor package 100. The mold compound 118 is not shown in FIG. 7, to provide an unobstructed view of the elements encased by the mold compound 118.

In FIG. 7, a first metal strip or sheet 500 is connected at a first end 502 to a first part 504 of the first high-side phase/power lead 136 and at a second end 506 to a second end 508 of the first high-side phase/power lead 136. The first metal strip or sheet 500 spans the first structured metal frame 148 between the first part 504 and the second part 508 of the first high-side phase/power lead 136. In this embodiment, the first high-side phase/power lead 136 has a C-shape inside the molded package body and a part 148a of the first structured metal frame 148 is disposed in the open part of the C-shape. The first metal strip or sheet 500 is connected to both ends 502, 508 of the C-shape, spanning the part 148a of the first structured metal frame 148 disposed in the open part of the C-shape.

In FIG. 7, a second metal strip or sheet 510 is connected at a first end 512 to a first part 514 of the second high-side phase/power lead 138 and at a second end 516 to a second end 518 of the second high-side phase/power lead 138. The second metal strip or sheet 500 spans the first structured metal frame 148 between the first part 514 and the second part 518 of the second high-side phase/power lead 138. In this embodiment, the second high-side phase/power lead 138 has a C-shape inside the molded package body and a part 148b of the first structured metal frame 148 is disposed in the open part of the C-shape. The second metal strip or sheet 510 is connected to both ends 512, 518 of the C-shape, spanning the part 148b of the first structured metal frame 148 disposed in the open part of the C-shape. The two C-shaped parts of the high-side phase/power leads 136, 138 face one another in a symmetrical configuration about the longitudinal centerline A-A′ in FIG. 7. As previously explained herein, both the first power semiconductor dies 108 and the second power semiconductor dies 116 may be equally distributed on both sides of the longitudinal centerline A-A′.

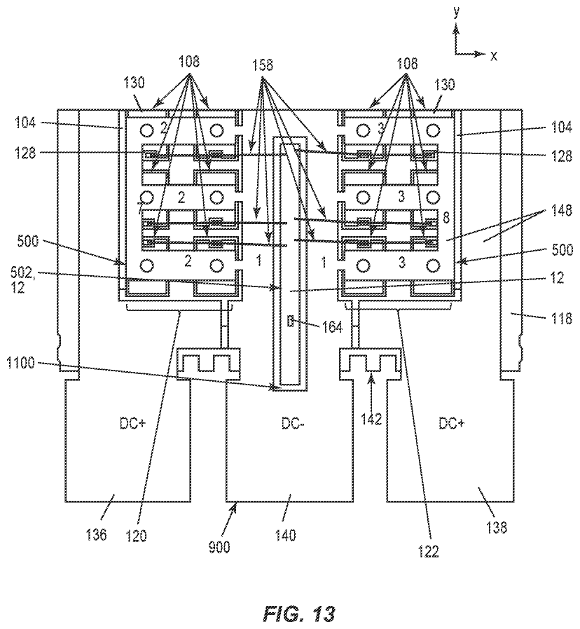

For the molded power semiconductor package and production embodiments described above and according to which the die gate connections ‘12’, ‘14’ are provided by part of the lead frames 148, 150, the following embodiments describe how the lead frame gate connections ‘12’, ‘14’ may be realized. In the following embodiment, the gate metallizations ‘12’, ‘14’ are initially part of the respective lead frames 148, 150 which also provide power leads 136, 138, 140, 144 and therefore cannot be used electrically until disconnected from the leads 136, 138, 140, 144. The gate metallization part ‘12’, ‘14’ of the lead frames 148, 150 are fixed through the molding process to ensure proper assembly. The gate metallization part 12′, ‘14’ of the lead frames 148, 150 are separated after the molding process to ensure no shorting between the gate metallizations ‘12’, ‘14’ and the power leads 136, 138, 140, 144 of the molded package 100. FIGS. 8 through 12 illustrate a first embodiment of producing the lead frame gate connections ‘12’, ‘14’. FIG. 13 illustrates a second embodiment of producing the lead frame gate connections ‘12’, ‘14’.

FIG. 8 illustrates a partial top plan view of the molded power semiconductor package 100 shown in FIG. 1 in the region of the first structured metal frame 148, prior to molding. As previously described in connection with FIG. 1, the first lead frame 148 is disposed above first power semiconductor dies 108. A first part 500 of the first lead frame 148 includes branches ‘2’ electrically connected to a first (e.g., source) load terminal 130 of the first power semiconductor dies 108. A second part 502 of the first lead frame 148 is spaced inward from the branches ‘2’ of the first part 500 and electrically connected to a gate terminal 128 of the first power semiconductor dies 108, e.g., by bond wires 158 such as Al, Cu, Ag, Al/Cu, Cu/Ag wires, a flexible PCB by soldering or sintering, etc.

The second part 502 of the first lead frame 148 corresponds to the first gate metallization ‘12’ shown in FIGS. 1, 6A, and 7. In FIG. 8, the second part 502 of the first lead frame 148 is integrally connected to the first part 500 of the first lead frame 148 to ensure proper assembly. Otherwise, if the second part 502 of the first lead frame 148 was not anchored prior to molding, movement of the second part 502 of the first lead frame 148 could result in improper or faulty connections between the first gate metallization ‘12’ and the gate terminal 128 of the first power semiconductor dies 108. In FIG. 8, the second part 502 of the first lead frame 148 is integrally connected to the part of the first lead frame 148 that forms the low-side phase/ground lead 140 of the molded power semiconductor package 100. This integral connection is severed after the molding process, to ensure the gate terminal 128 of the first power semiconductor dies 108 are not shorted to any of the power leads 136, 138, 140 provided by the first lead frame 148.

As shown in FIGS. 1 through 7, the molded power semiconductor package 100 also may include a second lead frame 150 above second power semiconductor dies 116 and electrically connected to the second power semiconductor dies 116 as previously described herein, e.g., to form a half bridge or other type of power electronics device. The second lead frame 150 and second power semiconductor dies 116 are not shown in FIGS. 8 through 13. However, the embodiments for producing the lead frame gate connection ‘12’ from the first lead frame 148 and described in connection with FIGS. 8 through 13 equally apply to the second lead frame 150.

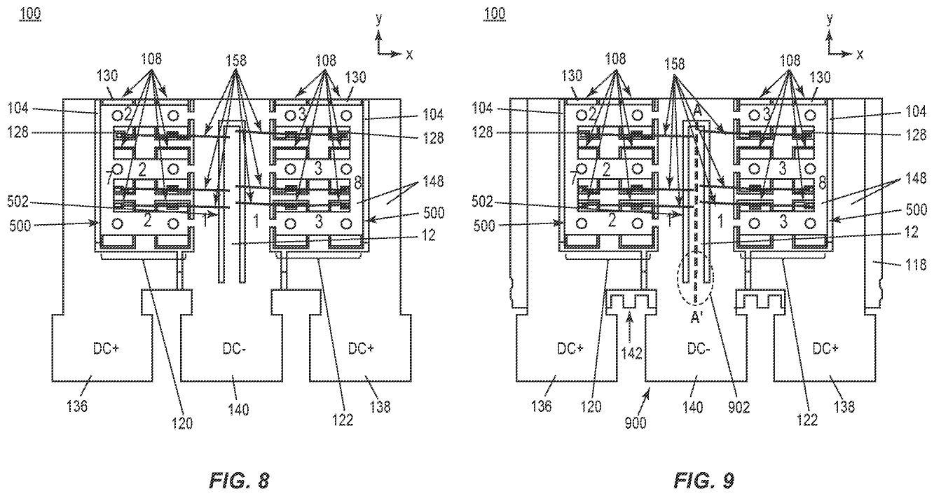

FIG. 9 illustrates a partial top plan view of the package structure of FIG. 8, after molding. The mold compound 118 is only shown around the edge of the package structure in FIG. 9, to provide an unobstructed view of the elements encased by the mold compound 118. The first part 500 of the first lead frame 148 has a protrusion 900 that juts out from a first side face 142 of the mold compound 118 to form a first lead 140 (e.g., DC−) of the molded power semiconductor package 100. A longitudinal axis A-A′ of the second part 502 of the first lead frame 148 intersects the first lead 140, e.g., in the region where the second part 502 of the first lead frame 148 is integrally connected to the first part 500 of the first lead frame 148.

In FIG. 9, the dashed oval labelled 902 (also referred to herein as ‘severing region’) indicates a region of the mold compound 118 that corresponds to where, after the molding, the integral connection between the first part 502 and the second part 500 of the first lead frame 148 is to be severed such that the first lead 140 becomes physically disconnected from the second part 502 of the first lead frame 148 and the second part 502 of the first lead frame 148 forms the first gate metallization ‘12’. According to this embodiment, the first part 502 of the first lead frame 148 is mechanically and electrically separated from the second part 500 of the first lead frame 148 in the severing region 902 of the mold compound 118 after the molding.

In FIG. 9, the integral connection between the first part 500 and the second part 502 of the first lead frame 148 is severed inside the perimeter of the mold compound 118. As explained above, the second lead frame 150, if provided, may be processed in the same or similar manner as the first lead frame 148 such that an integral connection between the switch node lead 144 and the second gate metallization ‘14’ both provided by the second lead frame 150 is severed to ensure proper electrical isolation between these nodes of the molded power semiconductor package 100.

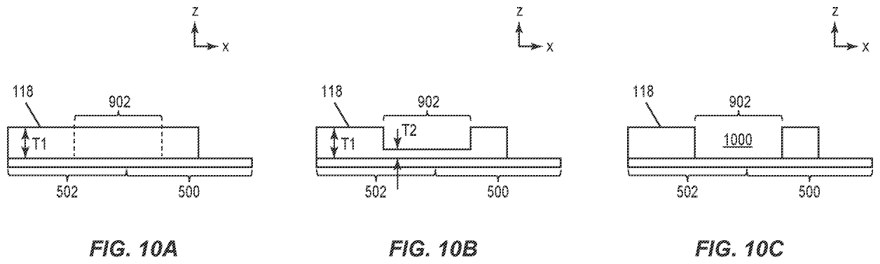

FIGS. 10A through 10C illustrate different embodiments of the severing region 902 of the mold compound 118 where, after the molding, the integral connection between the first part 502 and the second part 500 of the first lead frame 148 is to be severed. In FIG. 10A, the mold compound 118 has not been processed differently in the severing region 902 during the molding process. Accordingly, the thickness T1 of the mold compound 118 in the severing region 902 is unmodified during the molding process.

In FIG. 10B, the thickness of the mold compound 118 is reduced (T1=>T2) over the integral connection between the first part 502 and the second part 500 of the first lead frame 148 that is to be severed after the molding. For example, the mold compound 118 may have a down-set up to the first lead frame 148 with partial mold compound thickness reduction. The mold compound 118 may be formed by transfer molding to yield the reduced thickness T2 in the severing region 902 of the mold compound 118.

In FIG. 10C, an opening 1000 is formed in the mold compound 118 over the integral connection between the first part 502 and the second part 500 of the first lead frame 148 that is to be severed after the molding. For example, the mold compound 118 may be formed by transfer molding to yield the opening 1000 in the region 902 of the mold compound 118 that corresponds to where, after the molding, the integral connection between the first part 502 and the second part 500 of the first lead frame 148 is to be severed. In another embodiment, a fixed pin may be inserted in a cavity of a molding tool for preventing liquified mold compound from entering the severing region 902.

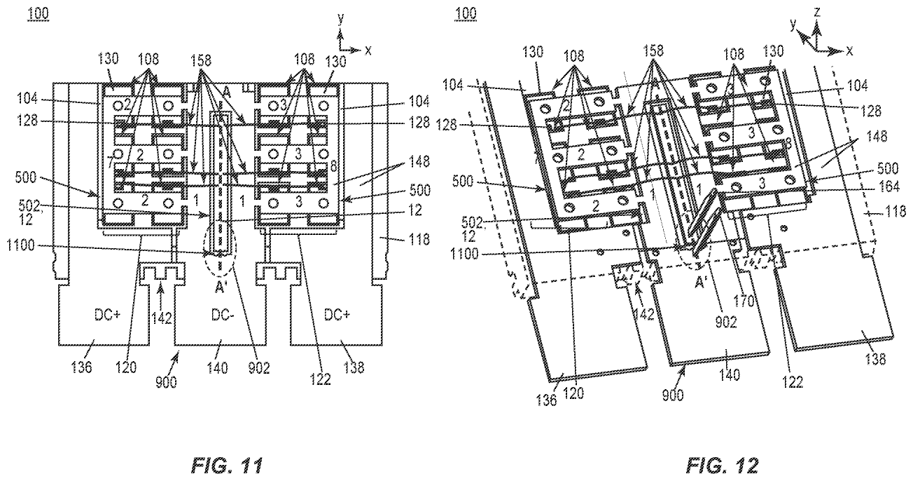

FIG. 11 illustrates a partial top plan view of the package structure of FIG. 9, after severing the integral connection between the first part 500 and the second part 502 of the first lead frame 148. The mold compound 118 is only shown around the edge of the package structure in FIG. 11, to provide an unobstructed view of the elements encased by the mold compound 118. The severing region 902 of the mold compound 118 in FIG. 11 corresponds to the embodiment illustrated in FIG. 10C. However, this is just an example. The severing region 902 of the mold compound 118 instead may be implemented as shown in FIG. 10A or FIG. 10B. In each case, and after the severing, the first lead 140 of the molded power semiconductor package 100 is physically disconnected from the first gate metallization ‘12’ of the package 100, where both the first lead 140 and the first gate metallization ‘12’ are provided by the first lead frame 148.

In one embodiment, the integral connection between the first part 500 and the second part 502 of the first lead frame 148 is severed by drilling the second part 502 of the first lead frame 148 inside the perimeter of the mold compound 118, e.g., using a micro drill. In another embodiment, the integral connection between the first part 500 and the second part 502 of the first lead frame 148 is severed by machining the second part 502 of the first lead frame 148 inside the perimeter of the mold compound 118, e.g., using a saw blade. In the case of severing the integral connection by drilling or machining, a stop may be used based on the lead frame thickness, e.g., as used in PCB (printed circuit board) machining or drilling processes. In another embodiment, the integral connection between the first part 500 and the second part 502 of the first lead frame 148 is severed by laser cutting the second part 502 of the first lead frame 148 inside the perimeter of the mold compound 118. In each case, the resulting severed region 1100 of the first lead frame 148 includes a plurality of interconnected drilled regions, a machined region, or a laser cut region inside the perimeter of the mold compound 118.

The severed region 1100 of the first lead frame 148 is shown as a plurality of interconnected drilled regions in FIG. 11, as an example. Although out of view in FIG. 11, the switch node lead 144 and the second gate metallization ‘14’ both provided by the second lead frame 150 may be similarly severed inside the perimeter of the mold compound 118. Accordingly, the second lead frame 150 may have a severed region 1102 as shown in FIGS. 1, 6A and 7, and that includes a plurality of interconnected drilled regions, a machined region, or a laser cut region inside the perimeter of the mold compound 118.

FIG. 12 illustrates a partial side perspective view of the package structure of FIG. 11, after attaching a press-fit pin 164 to the second part 502/first gate metallization ‘12’ of the first lead frame 148. The press-fit pin 164 extends outward from the front surface of the mold compound 118, where the first side face 142 of the mold compound 118 extends between the front surface and a back surface of the mold compound 118. In FIG. 12, the press-fit pin 164 is attached to the second part 502/first gate metallization ‘12’ of the first lead frame 148 in the severing region 902 of the mold compound 118.

For the severing region embodiment shown in FIG. 10C, the press-fit pin 164 is attached to the second part 502/first gate metallization ‘12’ of the first lead frame 148 through the opening 1000 in the mold compound 118. For the severing region embodiments shown in FIGS. 10A and 10B, the press-fit pin 164 is attached to the second part 502/first gate metallization ‘12’ of the first lead frame 148 by drilling a hole in the mold compound 118 in the severing region 902 and pressing the pin 164 into the hole. An additional press-fit pin 170 may be attached to the protrusion 900 of the first part 500 of the first lead frame 148 that juts out from the first side face 142 of the mold compound 118 to form a power lead 140. The additional press-fit pin 170 may be attached to the first part 500/power lead 140 of the second lead frame 150 in the severing region 902 of the mold compound 118 or outside the severing region 902.

FIG. 13 illustrates a partial top plan view of another embodiment of the molded power semiconductor package 100 in the region of the first structured metal frame 148, after molding. The mold compound 118 is only shown around the edge of the package structure in FIG. 13, to provide an unobstructed view of the elements encased by the mold compound 118. In FIG. 13, the integral connection between the first part 500 and the second part 502 of the first lead frame 148 is severed outside the mold compound 118. In one embodiment, the severing is performed by stamping the integral connection between the first part 500 and the second part 502 of the first lead frame 148 outside the mold compound 118 such that the severed region 1100 of the first lead frame 148 is a stamped region. For example, a trim and form process may be used to sever the integral connection between the first part 500 and the second part 502 of the first lead frame 148 outside the mold compound 118. Although out of view in FIG. 13, the switch node lead 144 and the second gate metallization ‘14’ both provided by the second lead frame 150 may be similarly severed outside the perimeter of the mold compound 118.

Although the present disclosure is not so limited, the following numbered examples demonstrate one or more aspects of the disclosure.

Example 1. A molded power semiconductor package, comprising: a mold compound; a plurality of first power semiconductor dies embedded in the mold compound; and a first lead frame embedded in the mold compound above the plurality of first power semiconductor dies, wherein a first part of the first lead frame comprises a plurality of branches electrically connected to a first load terminal of the first power semiconductor dies, wherein a second part of the first lead frame is spaced inward from the branches of the first part, and electrically connected to a gate terminal of the first power semiconductor dies, wherein the first part of the first lead frame has a protrusion that juts out from a first side face of the mold compound to form a first lead of the molded power semiconductor package, wherein a longitudinal axis of the second part of the first lead frame intersects the first lead, wherein the second part of the first lead frame is physically disconnected from the first lead by a severed region of the first lead frame.

Example 2. The molded power semiconductor package of example 1, wherein the severed region of the first lead frame is positioned inside a perimeter of the mold compound.

Example 3. The molded power semiconductor package of example 2, wherein the severed region of the first lead frame comprises a plurality of interconnected drilled regions, a machined region, or a laser cut region.

Example 4. The molded power semiconductor package of example 2 or 3, wherein the mold compound has a reduced thickness over the severed region of the first lead frame or is completely removed over the severed region of the first lead frame.

Example 5. The molded power semiconductor package of example 1, wherein the severed region of the first lead frame is positioned outside the mold compound.

Example 6. The molded power semiconductor package of example 5, wherein the severed region of the first lead frame comprises a stamped region.

Example 7. The molded power semiconductor package of any of examples 1 through 6, further comprising: a press-fit pin attached to the second part of the first lead frame and extending outward from a front surface of the mold compound, wherein the first side face of the mold compound extends between the front surface and a back surface of the mold compound.

Example 8. The molded power semiconductor package of any of examples 1 through 7, further comprising: a plurality of second power semiconductor dies embedded in the mold compound and electrically connected to the plurality of first power semiconductor dies to form a half bridge; and a second lead frame embedded in the mold compound above the plurality of second power semiconductor dies, wherein a first part of the second lead frame comprises a plurality of branches electrically connected to a first load terminal of the second power semiconductor dies, wherein a second part of the second lead frame is spaced inward from the branches of the first part of the second lead frame, and electrically connected to a gate terminal of the second power semiconductor dies, wherein the first part of the second lead frame has a protrusion that juts out from a second side face of the mold compound opposite the first side face to form a second lead of the molded power semiconductor package, wherein a longitudinal axis of the second part of the second lead frame intersects the second lead, wherein the second part of the second lead frame is physically disconnected from the second lead by a severed region of the second lead frame.

Example 9. The molded power semiconductor package of example 8, wherein both the severed region of the first lead frame and the severed region of the second lead frame are positioned inside a perimeter of the mold compound, wherein the mold compound has a reduced thickness over the severed region of the first lead frame or is completely removed over the severed region of the first lead frame, and wherein the mold compound has a reduced thickness over the severed region of the second lead frame or is completely removed over the severed region of the second lead frame.

Example 10. A method of producing a molded power semiconductor package, the method comprising: positioning a first lead frame above a plurality of first power semiconductor dies, the first lead frame comprising a first part and a second part integrally connected to one another, wherein the first part comprises a plurality of branches and the second part is spaced inward from the branches; electrically connecting the plurality of branches to a first load terminal of the first power semiconductor dies; electrically connecting the second part of the first lead frame to a gate terminal of the first power semiconductor dies; molding the first lead frame and the plurality of first power semiconductor dies with a mold compound, wherein the first part of the first lead frame has a protrusion that juts out from a first side face of the mold compound to form a first lead of the molded power semiconductor package and a longitudinal axis of the second part of the first lead frame intersects the first lead; and after the molding, severing the integral connection between the first part and the second part of the first lead frame such that the first lead becomes physically disconnected from the second part of the first lead frame.

Example 11. The method of example 10, wherein the integral connection between the first part and the second part of the first lead frame is severed inside a perimeter of the mold compound.

Example 12. The method of example 11, wherein severing the integral connection between the first part and the second part of the first lead frame comprises: drilling the second part of the first lead frame inside the perimeter of the mold compound.

Example 13. The method of example 11, wherein severing the integral connection between the first part and the second part of the first lead frame comprises: machining the second part of the first lead frame inside the perimeter of the mold compound.

Example 14. The method of example 11, wherein severing the integral connection between the first part and the second part of the first lead frame comprises: laser cutting the second part of the first lead frame inside the perimeter of the mold compound.

Example 15. The method of any of examples 11 through 14, wherein the molding comprises: reducing a thickness of the mold compound over the integral connection to be severed; or forming an opening in the mold compound over the integral connection to be severed.

Example 16. The method of example 10, wherein the integral connection between the first part and the second part of the first lead frame is severed outside the mold compound.

Example 17. The method of example 16, wherein severing the integral connection between the first part and the second part of the first lead frame comprises: stamping the integral connection between the first part and the second part of the first lead frame outside the mold compound.

Example 18. The method of any of examples 10 through 17, further comprising: before the molding, positioning a second lead frame above a plurality of second power semiconductor dies, the second lead frame comprising a first part and a second part integrally connected to one another, wherein the first part of the second lead frame comprises a plurality of branches and the second part of the second lead frame is spaced inward from the branches of the first part of the second lead frame; before the molding, electrically connecting the plurality of branches of the first part of the second lead frame to a first load terminal of the second power semiconductor dies, electrically connecting the second part of the second lead frame to a gate terminal of the second power semiconductor dies, and electrically interconnecting the plurality of second power semiconductor dies and the plurality of first power semiconductor dies to form a half bridge; as part of the molding, molding the second lead frame and the plurality of second power semiconductor dies with the mold compound, wherein the first part of the second lead frame has a protrusion that juts out from a second side face of the mold compound opposite the first side face to form a second lead of the molded power semiconductor package and a longitudinal axis of the second part of the second lead frame intersects the second lead; and after the molding, severing the integral connection between the first part and the second part of the second lead frame such that the second lead becomes physically disconnected from the second part of the second lead frame.

Example 19. The method of example 18, wherein the integral connection between the first part and the second part of the first lead frame is severed inside a perimeter of the mold compound, and wherein the integral connection between the first part and the second part of the second lead frame is severed inside the perimeter of the mold compound.

Example 20. The method of example 19, wherein the molding comprises: reducing a thickness of the mold compound over each of the integral connections to be severed; or forming an opening in the mold compound over each of the integral connections to be severed.

Example 21. The method of any of examples 18 through 20, wherein the integral connection between the first part and the second part of the first lead frame is severed outside the mold compound, and wherein the integral connection between the first part and the second part of the second lead frame is severed outside the mold compound.

Example 22. The method of example 21, wherein severing each of the integral connections comprises: stamping, outside the mold compound, both the integral connection between the first part and the second part of the first lead frame and the integral connection between the first part and the second part of the second lead frame.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A molded power semiconductor package, comprising:
a mold compound;
a plurality of first power semiconductor dies embedded in the mold compound; and
a first lead frame embedded in the mold compound above the plurality of first power semiconductor dies,
wherein a first part of the first lead frame comprises a plurality of branches electrically connected to a first load terminal of the first power semiconductor dies,
wherein a second part of the first lead frame is spaced inward from the branches of the first part, and electrically connected to a gate terminal of the first power semiconductor dies,
wherein the first part of the first lead frame has a protrusion that juts out from a first side face of the mold compound to form a first lead of the molded power semiconductor package,
wherein a longitudinal axis of the second part of the first lead frame intersects the first lead,
wherein the second part of the first lead frame is physically disconnected from the first lead by a severed region of the first lead frame.

2. The molded power semiconductor package of claim 1, wherein the severed region of the first lead frame is positioned inside a perimeter of the mold compound.

3. The molded power semiconductor package of claim 2, wherein the severed region of the first lead frame comprises a plurality of interconnected drilled regions, a machined region, or a laser cut region.

4. The molded power semiconductor package of claim 2, wherein the mold compound has a reduced thickness over the severed region of the first lead frame or is completely removed over the severed region of the first lead frame.

5. The molded power semiconductor package of claim 1, wherein the severed region of the first lead frame is positioned outside the mold compound.

6. The molded power semiconductor package of claim 5, wherein the severed region of the first lead frame comprises a stamped region.

7. The molded power semiconductor package of claim 1, further comprising:
a press-fit pin attached to the second part of the first lead frame and extending outward from a front surface of the mold compound,
wherein the first side face of the mold compound extends between the front surface and a back surface of the mold compound.

8. The molded power semiconductor package of claim 1, further comprising:
a plurality of second power semiconductor dies embedded in the mold compound and electrically connected to the plurality of first power semiconductor dies to form a half bridge; and
a second lead frame embedded in the mold compound above the plurality of second power semiconductor dies,
wherein a first part of the second lead frame comprises a plurality of branches electrically connected to a first load terminal of the second power semiconductor dies,
wherein a second part of the second lead frame is spaced inward from the branches of the first part of the second lead frame, and electrically connected to a gate terminal of the second power semiconductor dies,
wherein the first part of the second lead frame has a protrusion that juts out from a second side face of the mold compound opposite the first side face to form a second lead of the molded power semiconductor package,
wherein a longitudinal axis of the second part of the second lead frame intersects the second lead,
wherein the second part of the second lead frame is physically disconnected from the second lead by a severed region of the second lead frame.

9. The molded power semiconductor package of claim 8, wherein both the severed region of the first lead frame and the severed region of the second lead frame are positioned inside a perimeter of the mold compound, wherein the mold compound has a reduced thickness over the severed region of the first lead frame or is completely removed over the severed region of the first lead frame, and wherein the mold compound has a reduced thickness over the severed region of the second lead frame or is completely removed over the severed region of the second lead frame.

10. A method of producing a molded power semiconductor package, the method comprising:
positioning a first lead frame above a plurality of first power semiconductor dies, the first lead frame comprising a first part and a second part integrally connected to one another, wherein the first part comprises a plurality of branches and the second part is spaced inward from the branches;
electrically connecting the plurality of branches to a first load terminal of the first power semiconductor dies;
electrically connecting the second part of the first lead frame to a gate terminal of the first power semiconductor dies;
molding the first lead frame and the plurality of first power semiconductor dies with a mold compound, wherein the first part of the first lead frame has a protrusion that juts out from a first side face of the mold compound to form a first lead of the molded power semiconductor package and a longitudinal axis of the second part of the first lead frame intersects the first lead; and
after the molding, severing the integral connection between the first part and the second part of the first lead frame such that the first lead becomes physically disconnected from the second part of the first lead frame.

11. The method of claim 10, wherein the integral connection between the first part and the second part of the first lead frame is severed inside a perimeter of the mold compound.

12. The method of claim 11, wherein severing the integral connection between the first part and the second part of the first lead frame comprises:
drilling the second part of the first lead frame inside the perimeter of the mold compound.

13. The method of claim 11, wherein severing the integral connection between the first part and the second part of the first lead frame comprises:
machining the second part of the first lead frame inside the perimeter of the mold compound.

14. The method of claim 11, wherein severing the integral connection between the first part and the second part of the first lead frame comprises:
laser cutting the second part of the first lead frame inside the perimeter of the mold compound.

15. The method of claim 11, wherein the molding comprises:
reducing a thickness of the mold compound over the integral connection to be severed; or
forming an opening in the mold compound over the integral connection to be severed.

16. The method of claim 10, wherein the integral connection between the first part and the second part of the first lead frame is severed outside the mold compound.

17. The method of claim 16, wherein severing the integral connection between the first part and the second part of the first lead frame comprises:
stamping the integral connection between the first part and the second part of the first lead frame outside the mold compound.

18. The method of claim 10, further comprising:
before the molding, positioning a second lead frame above a plurality of second power semiconductor dies, the second lead frame comprising a first part and a second part integrally connected to one another, wherein the first part of the second lead frame comprises a plurality of branches and the second part of the second lead frame is spaced inward from the branches of the first part of the second lead frame;
before the molding, electrically connecting the plurality of branches of the first part of the second lead frame to a first load terminal of the second power semiconductor dies, electrically connecting the second part of the second lead frame to a gate terminal of the second power semiconductor dies, and electrically interconnecting the plurality of second power semiconductor dies and the plurality of first power semiconductor dies to form a half bridge;
as part of the molding, molding the second lead frame and the plurality of second power semiconductor dies with the mold compound, wherein the first part of the second lead frame has a protrusion that juts out from a second side face of the mold compound opposite the first side face to form a second lead of the molded power semiconductor package and a longitudinal axis of the second part of the second lead frame intersects the second lead; and
after the molding, severing the integral connection between the first part and the second part of the second lead frame such that the second lead becomes physically disconnected from the second part of the second lead frame.

19. The method of claim 18, wherein the integral connection between the first part and the second part of the first lead frame is severed inside a perimeter of the mold compound, and wherein the integral connection between the first part and the second part of the second lead frame is severed inside the perimeter of the mold compound.

20. The method of claim 19, wherein the molding comprises:
reducing a thickness of the mold compound over each of the integral connections to be severed; or
forming an opening in the mold compound over each of the integral connections to be severed.

21. The method of claim 18, wherein the integral connection between the first part and the second part of the first lead frame is severed outside the mold compound, and wherein the integral connection between the first part and the second part of the second lead frame is severed outside the mold compound.

22. The method of claim 21, wherein severing each of the integral connections comprises: stamping, outside the mold compound, both the integral connection between the first part and the second part of the first lead frame and the integral connection between the first part and the second part of the second lead frame.
